(19) United States
(12) Patent Application Publication
(10) Pub. No.: US 2026/0098880 A1
(43) Pub. Date: Apr. 9, 2026

(54) COUPLING STATE DETECTION DEVICE AND DETECTION METHOD THEREOF

(71) Applicants: Yi-Chung Chou, Taipei City (TW); Dong-Shan Chen, Hsinchu County (TW); Shao-Wen Liu, Kaohsiung City (TW)

(72) Inventors: Yi-Chung Chou, Taipei City (TW); Dong-Shan Chen, Hsinchu County (TW); Shao-Wen Liu, Kaohsiung City (TW)

(73) Assignee: ITE Tech. Inc., Hsinchu (TW)

(21) Appl. No.: 19/034,463

(22) Filed: Jan. 22, 2025

(30) Foreign Application Priority Data
Oct. 7, 2024 (TW) 113138135

(51) Int. Cl. G01R 19/00; H03K 17/56

(52) U.S. Cl. CPC G01R 19/0038; H03K 17/56

(57) ABSTRACT

Provided are a coupling state detection device and a detection method thereof. A control circuit controls a switching circuit to switch an output end of a transmitter to connect to a resistance circuit or a voltage pulse generating circuit, controls the voltage pulse generating circuit to generate a voltage pulse, and determines a coupling state between the transmitter and a receiver according to a detection signal generated by detecting output voltages of the transmitter by a detection circuit when the switching circuit is connected to the resistance circuit and when the switching circuit is connected to the voltage pulse generating circuit.

### CROSS-REFERENCE TO RELATED APPLICATION

This application claims the priority benefit of Taiwan application serial no. 113138135, filed on Oct. 7, 2024. The entirety of the above-mentioned patent application is hereby incorporated by reference herein and made a part of this specification.

### BACKGROUND

### Technical Field

This disclosure relates to a detection device, and in particular to a coupling state detection device and a detection method thereof.

### Description of Related Art

In high-speed transmission applications, the transmitter and receiver may be AC coupled or DC coupled. Due to the different coupling methods, the resistor connection needs to be adjusted accordingly at the transmitter side of the high-speed signal, so an external setting is usually required to inform the transmitter of the coupling method between the transmitter and receiver.

### SUMMARY

The disclosure provides a detection method of a coupling state detection device, capable of determining automatically a coupling method between the transmitter and a receiver without the need to notify the transmitter through an external setting.

The coupling state detection device of the disclosure is adapted to detect a coupling state of a transmitter. The coupling state detection device includes a switching circuit, a resistance circuit, a voltage pulse generating circuit, a detection circuit, and a control circuit. The switching circuit is coupled to an output end of the transmitter. The resistance circuit is coupled between the switching circuit and a first reference voltage. The voltage pulse generating circuit is coupled to the switching circuit. The detection circuit is coupled to the output end of the transmitter, detects an output voltage of the transmitter to generate a detection signal. The control circuit is coupled to the transmitter, the switching circuit, the voltage pulse generating circuit, and the detection circuit. The control circuit controls the switching circuit to switch to connect to the resistance circuit or the voltage pulse generating circuit, controls the voltage pulse generating circuit to generate a voltage pulse, and determines a coupling state between the transmitter and a receiver according to the detection signal generated by detecting the output voltage of the transmitter by the detection circuit when the switching circuit is connected to the resistance circuit and when the switching circuit is connected to the voltage pulse generating circuit.

In an embodiment of the disclosure, the coupling state between the transmitter and the receiver includes whether the transmitter is connected to the receiver, and whether the transmitter and the receiver are AC coupling or DC coupling.

In an embodiment of the disclosure, the switching circuit includes a first switch and a second switch. The first switch is coupled between the output end of the transmitter and the resistance circuit. The second switch is coupled between the output end of the transmitter and the voltage pulse generating circuit. Conduction states of the first switch and the second switch are controlled by the control circuit. When one of the first switch and the second switch is turned on, the other one of the first switch and the second switch is turned off.

In an embodiment of the disclosure, the detection circuit includes a comparator. A positive input end and a negative input end of the comparator are respectively coupled to the output end of the transmitter and a second reference voltage, an output end of the comparator is coupled to the control circuit, and the comparator compares an output voltage of the transmitter and the second reference voltage to generate the detection signal.

In an embodiment of the disclosure, the control circuit controls the voltage pulse generating circuit to generate the voltage pulse after the switching circuit switches to connect to the voltage pulse generating circuit.

In an embodiment of the disclosure, the resistance circuit includes a resistor or a current source.

The disclosure also provides a detection method of a coupling state detection device, adapted to detect a coupling state of a transmitter. The coupling state detection device includes a switching circuit, a resistance circuit, a voltage pulse generating circuit, and a detection circuit. The switching circuit is coupled to an output end of the transmitter. The resistance circuit is coupled between the switching circuit and a reference voltage. The voltage pulse generating circuit is coupled to the switching circuit. The detection circuit is coupled to the output end of the transmitter. The detection method of the coupling state detection device includes the following. The switching circuit is controlled to switch to connect to the resistance circuit, and a first detection signal generated by detecting an output voltage of the transmitter by the detection circuit is received. The switching circuit is controlled to switch to connect to the voltage pulse generating circuit, and a second detection signal generated by detecting the output voltage of the transmitter by the detection circuit is received. A coupling state between the transmitter and a receiver is determined according to the first detection signal and the second detection signal.

In an embodiment of the disclosure, the coupling state between the transmitter and the receiver includes whether the transmitter is connected to the receiver, and whether the transmitter and the receiver are AC coupling or DC coupling.

In an embodiment of the disclosure, the switching circuit includes a first switch and a second switch. The first switch is coupled between the output end of the transmitter and the resistance circuit, and the second switch is coupled between the output end of the transmitter and the voltage pulse generating circuit. When one of the first switch and the second switch is turned on, the other one of the first switch and the second switch is turned off.

In an embodiment of the disclosure, the detection method of the coupling state detection device includes that after the switching circuit switches to connect to the voltage pulse generating circuit, the voltage pulse generating circuit is controlled to generate the voltage pulse.

Based on the above, the control circuit of the embodiment of the disclosure can control the switching circuit to switch the output end of the transmitter to connect to the resistance circuit or the voltage pulse generating circuit, control the voltage pulse generating circuit to generate the voltage pulse, and determine the coupling state between the transmitter and receiver according to the detection signal generated by detecting the output voltage of the transmitter by the detection circuit when the switching circuit is connected to the resistance circuit and when the switching circuit is connected to the voltage pulse generating circuit. In this way, the coupling between the transmitter and the receiver can be determined automatically without the need to notify the transmitter of the coupling between the transmitter and the receiver through an external setting.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1A to FIG. 1D are schematic diagrams of coupling states of a transmitter and a receiver according to an embodiment of the disclosure.

FIG. 2 is a schematic diagram of a coupling state detection device according to an embodiment of the disclosure.

FIG. 3 is a flow chart of operation of a coupling state detection device according to an embodiment of the disclosure.

FIG. 4 to FIG. 7 are schematic diagrams of operation sequence of a coupling state detection device according to an embodiment of the disclosure.

FIG. 8 is a schematic diagram of a transmitter according to an embodiment of the disclosure.

FIG. 9 is a flow chart of a detection method of a coupling state detection device according to an embodiment of the disclosure.

### DESCRIPTION OF THE EMBODIMENTS

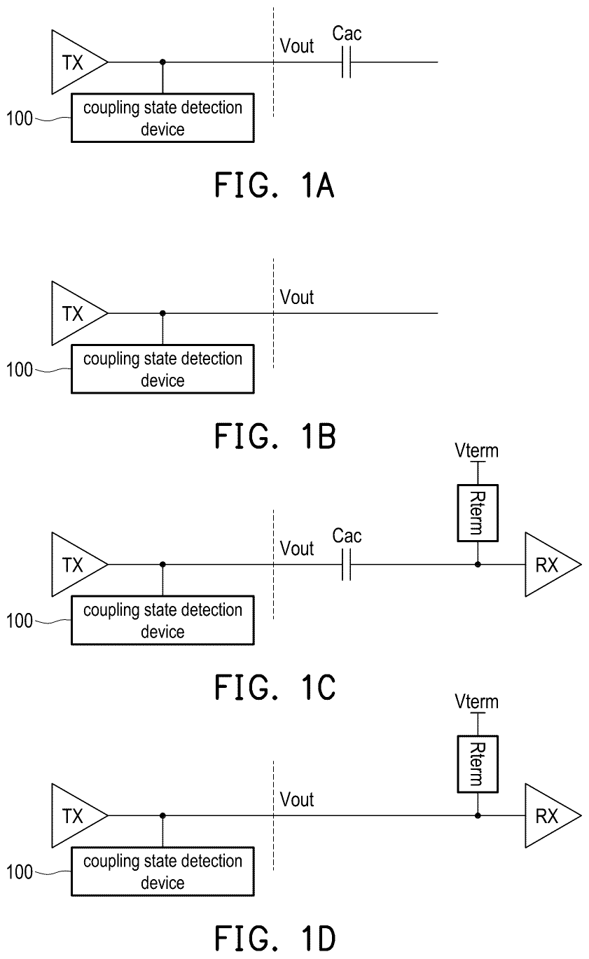

FIG. 1A is a schematic diagram of a coupling state of a transmitter and a receiver according to an embodiment of the disclosure. As shown in FIG. 1, a coupling state detection device 100 is coupled to an output end of a transmitter TX. The coupling state between the transmitter TX and a receiver RX can be shown in FIG. 1A to FIG. 1D, including an AC coupling mode but the transmitter TX not coupled to the receiver RX, a DC coupling mode but the transmitter TX not coupled to the receiver RX, the AC coupling mode and the transmitter TX coupled to the receiver RX, and the DC coupling mode and the transmitter TX coupled to the receiver RX. As shown in FIG. 1A and FIG. 1C, in the AC coupling mode, the output end of the transmitter TX is coupled to an AC coupling capacitor Cac. In addition, as shown in FIG. 1C and FIG. 1D, when the transmitter TX is coupled to the receiver RX, an input end of the receiver RX includes a terminal resistor Rterm coupled between the input end of the receiver RX and a terminal voltage Vterm.

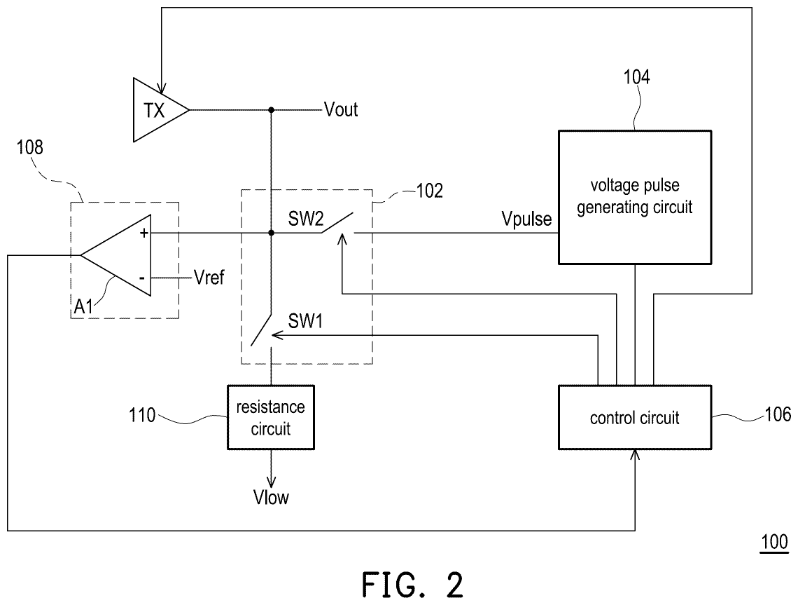

Furthermore, the implementation of the coupling state detection device 100 can be as shown in FIG. 2. The coupling state detection device 100 includes a switching circuit 102, a voltage pulse generating circuit 104, a control circuit 106, a detection circuit 108, and a resistance circuit 110. The switching circuit 102 is coupled to the output end of the transmitter TX, the voltage pulse generating circuit 104, the control circuit 106, the detection circuit 108, and the resistance circuit 110. The control circuit 106 is also coupled to the voltage pulse generating circuit 104 and the detection circuit 108. The resistance circuit 110 is also coupled to a reference voltage Vlow. The reference voltage Vlow may be, for example, a ground voltage or a preset voltage smaller than the terminal voltage Vterm.

The control circuit 106 can control the switching circuit 102 to switch to couple to the voltage pulse generating circuit 104 or the resistance circuit 110, and control the voltage pulse generating circuit 104 to generate a voltage pulse Vpulse. In this embodiment, the switching circuit 102 may include switches SW1 and SW2. The switch SW1 is coupled between the output end of the transmitter TX and the resistance circuit 110. The switch SW2 is coupled between the output end of the transmitter TX and the voltage pulse generating circuit 104. The conduction states of the switches SW1 and SW2 are controlled by the control circuit 106. When one of the switches SW1 and SW2 is turned on, the other of the switches SW1 and SW2 is turned off.

The detection circuit 108 can detect an output voltage Vout of the transmitter TX and generate a detection signal. In this embodiment, the detection circuit 108 can be implemented by, for example, a comparator A1, but is not limited thereto. The positive and negative input ends of the comparator A1 are respectively coupled to the output end of the transmitter TX and a reference voltage Vref. The comparator A1 can compare the output voltage Vout of the transmitter TX and the reference voltage Vref, and output the detection signal to the control circuit 106. Furthermore, the detection circuit 108 generates a corresponding detection signal corresponding to the switching state of the switching circuit 102. For example, when the switching circuit 102 is switched to connect to the resistance circuit 110, a first detection signal is generated by detecting the output voltage Vout of the transmitter TX, and when the circuit 102 is switched to connect to the voltage pulse generating circuit 104, a second detection signal is generated by detecting the output voltage Vout of the transmitter TX. When the switching circuit 102 is switched to connect to the voltage pulse generating circuit 104, the control circuit 106 can control the voltage pulse generating circuit 104 to generate the voltage pulse Vpulse, and provide the voltage pulse Vpulse to the output end that detects the transmitter TX. The control circuit 106 can determine the coupling state between the transmitter TX and the receiver RX according to the detection signal (including the first detection signal and the second detection signal) provided by the detection circuit 108.

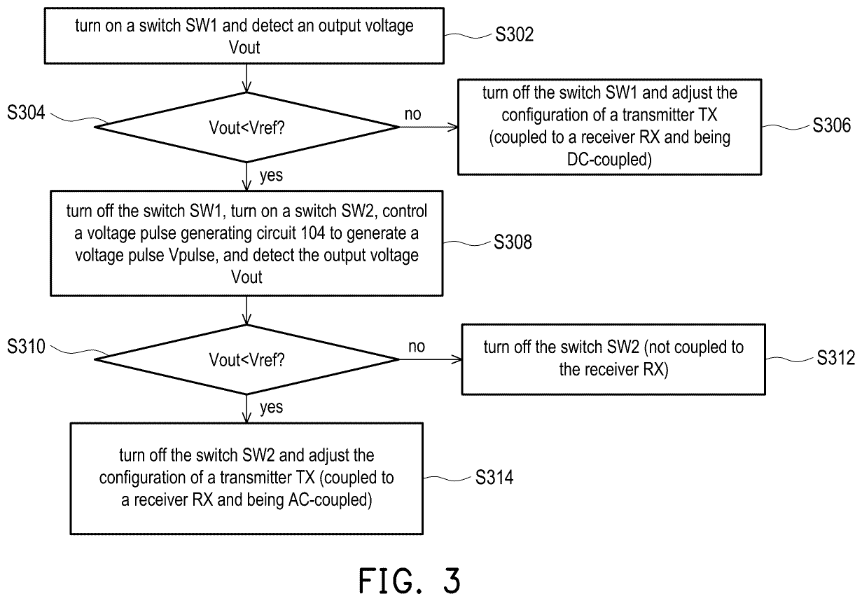

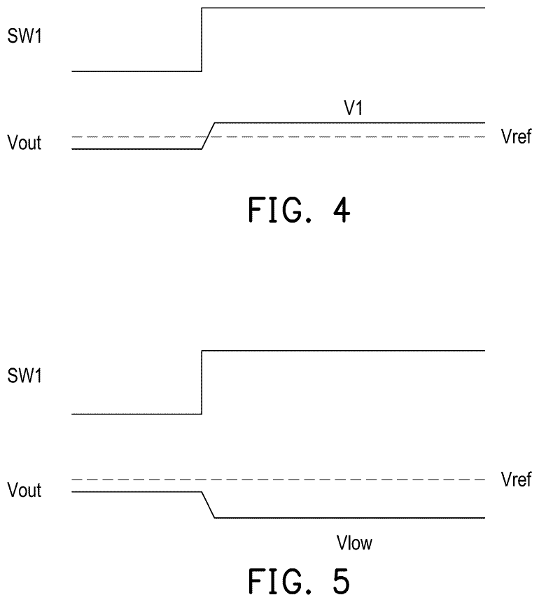

In detail, the way the control circuit 106 determines the coupling state between the transmitter TX and the receiver RX is as shown in FIG. 3. The control circuit 106 can first turn on the switch SW1 and turn off the switch SW2. At the same time, the detection circuit 108 can detect the output voltage Vout and generate a first detection signal (step S302). As shown in FIG. 4, after the switch SW1 is turned on, if the output voltage Vout rises to a voltage V1 as shown in FIG. 4, the voltage V1 is shown as the following formula (1) or (2).

V1=Vterm*Rdet/(Rdet+Rterm) (1)

V1=Vterm−Rterm*Idet (2)

The formula (1) is applicable to the situation when the resistance circuit 110 is implemented as a resistor, and Rdet is the resistance value of the resistance circuit 110. The formula (2) is applicable to the situation when the resistance circuit 110 is implemented as a current source, and Idet is the current provided by the resistance circuit 110.

The control circuit 106 can learn the change of the output voltage Vout according to the first detection signal provided by the detection circuit 108. For example, in the embodiment of FIG. 2, the relationship between the output voltage Vout and the reference voltage Vref can be determined according to the first detection signal (step S304). When the output voltage Vout is not less than the reference voltage Vref (e.g., the situation in the embodiment of FIG. 4), the control circuit 106 can determine that the transmitter TX is coupled to the receiver RX and there is a DC coupling between the transmitter TX and the receiver RX. At this time, the control circuit 106 can turn off the switch SW1 and adjust the configuration of the transmitter TX, so that the transmitter TX is suitable for DC-coupled signal transmission.

If in step S304, as shown in FIG. 5, the output voltage Vout drops to the reference voltage Vlow which is less than the reference voltage Vref, it means that the transmitter TX may not be coupled to the receiver RX, or the transmitter TX may be coupled to the receiver RX and be AC coupled. The control circuit 106 can then turn off the switch SW1, turn on the switch SW2, and control the voltage pulse generating circuit 104 to generate the voltage pulse Vpulse, while the detection circuit 108 detects the output voltage Vout and generates a second detection signal (step S308). The control circuit 106 can learn the change of the output voltage Vout according to the second detection signal provided by the detection circuit 108. For example, in the embodiment of FIG. 2, the relationship between the output voltage Vout and the reference voltage Vref can be determined according to the second detection signal (step S310).

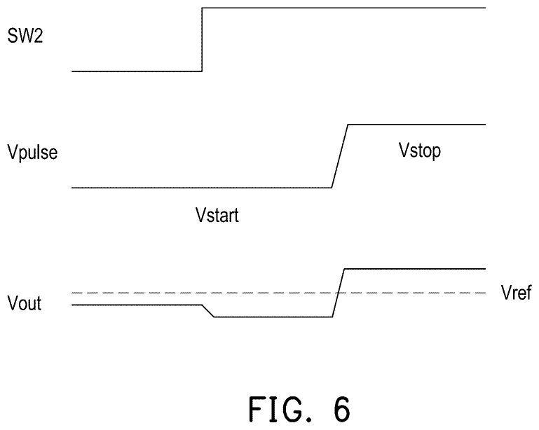

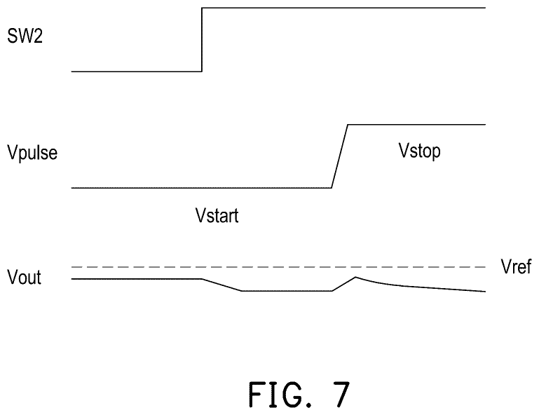

As shown in FIG. 6, if after the switch SW2 is turned on and the voltage pulse Vpulse rises from a voltage Vstart to a voltage Vstop, the output voltage Vout rises to a voltage higher than the reference voltage Vref, the control circuit 106 can determine that the transmitter TX is not coupled to the receiver RX according to the second detection signal provided by the detection circuit 108, and turns off the switch SW2 (step S312). And if in step S304, as shown in FIG. 7, after the voltage pulse Vpulse rises from the voltage Vstart to the voltage Vstop, the output voltage Vout only rises briefly and continues to be less than the reference voltage Vref, the control circuit 106 can determine that the transmitter TX is coupled to the receiver RX and is AC coupled according to the second detection signal provided by the detection circuit 108. At this time, the control circuit 106 can turn off the switch SW2 and adjust the configuration of the transmitter TX, so that the transmitter TX is suitable for AC-coupled signal transmission.

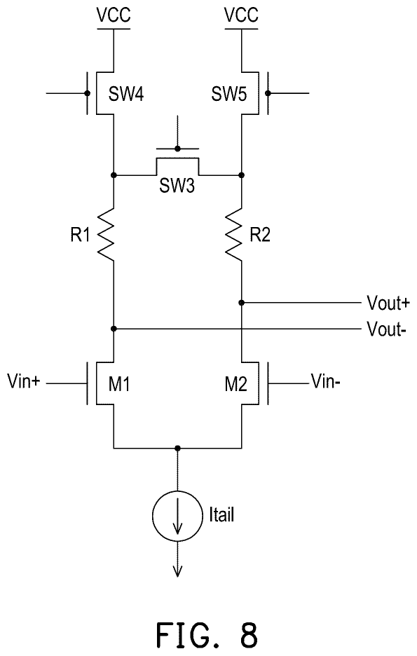

For example, the implementation of the transmitter TX can be shown in FIG. 8, consisting of switches SW4 to SW5, transistors M1 and M2, resistors R1 and R2, and a current source Itail. The transistors M1 and M2 are used to receive input voltages Vin+ and Vin−. When the transmitter TX and the receiver RX are DC coupled, the control circuit 106 can turn on the switch SW3 and turn off the switches SW4 and SW5 to establish the output impedance of the output end of the transmitter TX. When the transmitter TX and the receiver RX are AC coupled, the control circuit 106 can turn off the switch SW3 and turn on the switches SW4 and SW5 to establish a DC voltage level of the output end of the transmitter TX. In addition, when the transmitter TX is not coupled to the receiver RX, the switches SW3 to SW5 can be turned off and the current source Itail can be disabled. The voltage value of a voltage VCC can be set to the terminal voltage Vterm, for example, and the resistance values of the resistors R1 and R2 can be set to the terminal resistor Rterm, for example, but are not limited thereto.

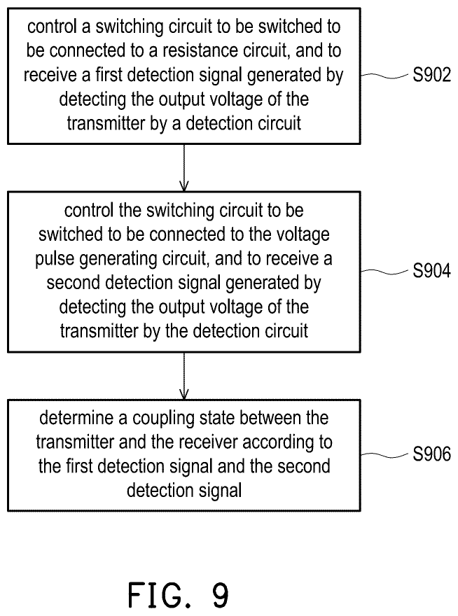

FIG. 9 is a flow chart of a detection method of a coupling state detection device according to an embodiment of the disclosure. The coupling state detection device includes switching circuit, resistance circuit, voltage pulse generating circuit, and detection circuit. The switching circuit is coupled to the output end of the transmitter. The resistance circuit is coupled between the switching circuit and the reference voltage. The voltage pulse generating circuit is coupled to the switching circuit, the detection circuit is coupled to the output end of the transmitter. The reference voltage may be, for example, the ground voltage, and the switching circuit may, for example, include a first switch and a second switch. The first switch is coupled between the output end of the transmitter and the resistance circuit, and the second switch is coupled between the output end of the transmitter and the voltage pulse generating circuit. When one of the first switch and the second switch is turned on, the other one of the first switch and the second switch is turned off. As can be seen from the above embodiments, the detection method of the coupling state detection device may include the following steps. First, the switching circuit is controlled to switch to couple to the resistance circuit, and receives a first detection signal generated by detecting the output voltage of the transmitter by the detection circuit (step S902). Then, the switching circuit is controlled to switch to couple to the voltage pulse generating circuit, and receives a second detection signal generated by detecting the output voltage of the transmitter by the detection circuit (step S904). The voltage pulse generating circuit may, for example, generate a voltage pulse after the switching circuit is switched to connect to the voltage pulse generating circuit, and in some embodiments may also, for example, generate a voltage pulse periodically. Then, the coupling state between the transmitter and the receiver is determined according to the first detection signal and the second detection signal (step S906). The coupling state between the transmitter and the receiver can include, for example, whether the transmitter is connected to the receiver, and whether the transmitter and the receiver are AC coupled or DC coupled.

To sum up, the control circuit of the embodiment of the disclosure can control the switching circuit to switch the output end of the transmitter to connect to the resistance circuit or the voltage pulse generating circuit, control the voltage pulse generating circuit to generate the voltage pulse, and determine the coupling state between the transmitter and receiver according to the detection signal generated by detecting the output voltage of the transmitter by the detection circuit when the switching circuit is connected to the resistance circuit and when the switching circuit is connected to the voltage pulse generating circuit. In this way, the coupling between the transmitter and the receiver can be determined automatically without the need to notify the transmitter of the coupling between the transmitter and the receiver through an external setting.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A coupling state detection device, adapted to detect a coupling state of a transmitter, the coupling state detection device comprising:
a switching circuit, coupled to an output end of the transmitter;
a resistance circuit, coupled between the switching circuit and a first reference voltage;
a voltage pulse generating circuit, coupled to the switching circuit;
a detection circuit, coupled to the output end of the transmitter, detecting an output voltage of the transmitter to generate a detection signal; and
a control circuit, coupled to the transmitter, the switching circuit, the voltage pulse generating circuit, and the detection circuit, controlling the switching circuit to switch to connect to the resistance circuit or the voltage pulse generating circuit, and controlling the voltage pulse generating circuit to generate a voltage pulse, and determining a coupling state between the transmitter and a receiver according to the detection signal generated by detecting the output voltage of the transmitter by the detection circuit when the switching circuit is connected to the resistance circuit and when the switching circuit is connected to the voltage pulse generating circuit.

2. The coupling state detection device according to claim 1, wherein the coupling state between the transmitter and the receiver comprises whether the transmitter is connected to the receiver, and whether the transmitter and the receiver are AC coupling or DC coupling.

3. The coupling state detection device according to claim 1, wherein the switching circuit comprises:
a first switch, coupled between the output end of the transmitter and the resistance circuit; and
a second switch, coupled between the output end of the transmitter and the voltage pulse generating circuit, conduction states of the first switch and the second switch being controlled by the control circuit, wherein when one of the first switch and the second switch is turned on, the other one of the first switch and the second switch is turned off.

4. The coupling state detection device according to claim 1, wherein the detection circuit comprises:
a comparator, wherein a positive input end and a negative input end of the comparator are respectively coupled to the output end of the transmitter and a second reference voltage, an output end of the comparator is coupled to the control circuit, and the comparator compares an output voltage of the transmitter and the second reference voltage to generate the detection signal.

5. The coupling state detection device according to claim 1, wherein the control circuit controls the voltage pulse generating circuit to generate the voltage pulse after the switching circuit switches to connect to the voltage pulse generating circuit.

6. The coupling state detection device according to claim 1, wherein the resistance circuit comprises a resistor or a current source.

7. A detection method of a coupling state detection device, adapted to detect a coupling state of a transmitter, wherein the coupling state detection device comprises a switching circuit, a resistance circuit, a voltage pulse generating circuit, and a detection circuit, the switching circuit is coupled to an output end of the transmitter, the resistance circuit is coupled between the switching circuit and a reference voltage, the voltage pulse generating circuit is coupled to the switching circuit, the detection circuit is coupled to the output end of the transmitter, and the detection method of the coupling state detection device comprises:
controlling the switching circuit to switch to connect to the resistance circuit, and receiving a first detection signal generated by detecting an output voltage of the transmitter by the detection circuit;
controlling the switching circuit to switch to connect to the voltage pulse generating circuit, and receiving a second detection signal generated by detecting the output voltage of the transmitter by the detection circuit; and
determining a coupling state between the transmitter and a receiver according to the first detection signal and the second detection signal.

8. The detection method of the coupling state detection device according to claim 7, wherein the coupling state between the transmitter and the receiver comprises whether the transmitter is connected to the receiver, and whether the transmitter and the receiver are AC coupling or DC coupling.

9. The detection method of the coupling state detection device according to claim 7, wherein the switching circuit comprises a first switch and a second switch, the first switch is coupled between the output end of the transmitter and the resistance circuit, the second switch is coupled between the output end of the transmitter and the voltage pulse generating circuit, wherein when one of the first switch and the second switch is turned on, the other one of the first switch and the second switch is turned off.

10. The detection method of the coupling state detection device according to claim 7, comprising:
after the switching circuit switches to connect to the voltage pulse generating circuit, controlling the voltage pulse generating circuit to generate the voltage pulse.
